(19) United States
(12) Patent Application Publication
(10) Pub. No.: US 2026/0025973 A1
(43) Pub. Date: Jan. 22, 2026

(54) MEMORY DEVICE HAVING TIERS OF 2-TRANSISTOR MEMORY CELLS

(71) Applicant: Micron Technology, Inc., Boise, ID (US)

(72) Inventors: Kamal M. Karda, Boise, ID (US); Haitao Liu, Boise, ID (US); Durai Vishak Nirmal Ramaswamy, Boise, ID (US)

(21) Appl. No.: 19/269,800

(22) Filed: Jul. 15, 2025

Related U.S. Application Data
(60) Provisional application No. 63/672,030, filed on Jul. 16, 2024.

(51) Int. Cl. H10B 12/00

(52) U.S. Cl. CPC H10B 12/30

(57) ABSTRACT

Some embodiments include apparatuses and methods of using the apparatuses. One of the apparatuses includes: a first conductive structure located on a first level of the apparatus; a second conductive structure located on a second level of the apparatus, each of the first and second conductive structures including a length in a first direction; a memory cell including a first semiconductor portion located on the first level and coupled to the first conductive structure, a charge storage structure located on the first level and coupled to the first semiconductor portion, and a second semiconductor portion located on the second level and coupled to the second conductive structure; and a conductive region adjacent the first and second semiconductor portions, the conductive region including a length in a second direction and separated from the first and second semiconductor portions by a dielectric material.

### PRIORITY APPLICATION

This application claims the benefit of priority to U.S. Provisional Application Ser. No. 63/672,030, filed Jul. 16, 2024, which is incorporated herein by reference in its entirety.

### BACKGROUND

Memory devices are widely used in computers and many other electronic items to store information. Memory devices are generally categorized into two types: volatile memory devices and non-volatile memory devices. A memory device usually has numerous memory cells to store information. In a volatile memory device, information stored in the memory cells is lost if supply power is disconnected from the memory device. In a non-volatile memory device, information stored in the memory cells is retained even if supply power is disconnected from the memory device.

The description herein involves volatile memory devices. Most conventional volatile memory devices store information in the form of charge in a capacitor structure included in the memory cell. As demand for device storage density increases, many conventional techniques provide ways to shrink the size of the memory cell in order to increase device storage density for a given device area. However, physical limitations and fabrication constraints may pose a challenge to such conventional techniques if the memory cell size is to be shrunk to a certain dimension.

### BRIEF DESCRIPTION OF THE DRAWINGS

FIG. 1 shows a block diagram of an apparatus in the form of a memory device including volatile memory cells, according to some embodiments described herein.

FIG. 2 shows a schematic diagram of a portion of a memory device including a memory array of two-transistor (2T) memory cells, according to some embodiments described herein.

FIG. 3 shows the memory device of FIG. 2, including example voltages used during a read operation of the memory device, according to some embodiments described herein.

FIG. 4 shows the memory device of FIG. 2, including example voltages used during a write operation of the memory device, according to some embodiments described herein.

FIG. 5 shows the memory device of FIG. 2, including separate drivers coupled to access lines associated with a memory cell, according to some embodiments described herein.

FIG. 6A through FIG. 7 show different views of a structure of the memory device of FIG. 2 through FIG. 5 including multiple tiers of memory cells, according to some embodiments described herein.

### DETAILED DESCRIPTION

The memory device described herein includes volatile memory cells in which each of the memory cells can include two transistors (2T). One of the two transistors has a charge storage structure, which can form a memory element of the memory cell to store information.

The described memory device includes tiers that are stacked one over another over a substrate (e.g., a semiconductor substrate) of the memory device. Each tier has memory cells and associated access lines (e.g., word lines).

The access lines can be structured to include separate conductive regions (e.g., conductive strips) having lengths extending in a direction from one tier to another tier (e.g., extending vertically). The access lines (e.g., vertical access lines) are used to control the transistors of the memory cells of the tiers. The conductive regions of the access lines can be configured such that two transistors in a memory cell can be controlled by the same signal provided through the access lines or alternatively by separate signals (e.g., two different signals from two different drivers).

The described memory device includes data lines (e.g., bit lines) that can include conductive structures extending perpendicular to the access lines (e.g., extending horizontally). The memory cells of the same tiers can share the conductive structures of the data lines (e.g., horizonal data lines). Each memory cell of the described memory device can be associated with two data lines (e.g., a read data line and a write data line).

The described memory device includes common conductive structures (e.g., conductive plates) in addition to the conductive structures of the data lines. The common conductive structures can also extend through the tiers (e.g., extending vertically).

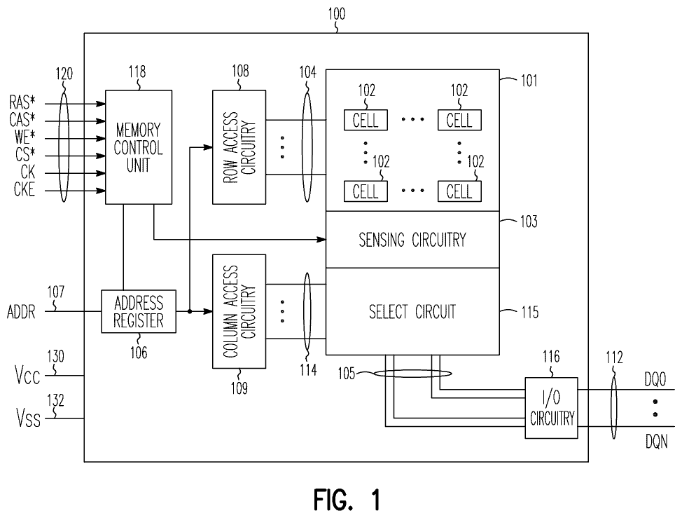

Improvements and benefits of the described memory device include improved device area efficiency and improved memory operations. Further, the tier structure of the described memory device can also improve (e.g., reduce) cost per bit of the memory device. Other improvements and benefits of the described memory device and its variations are discussed below with reference to FIG. 1 through FIG. 7.

FIG. 1 shows a block diagram of an apparatus in the form of a memory device 100 including volatile memory cells, according to some embodiments described herein. Memory device 100 includes a memory array 101, which can contain memory cells 102. Memory device 100 can include a volatile memory device such that memory cells 102 can be volatile memory cells. An example of memory device 100 includes a dynamic random-access memory (DRAM) device. Information stored in memory cells 102 of memory device 100 may be lost (e.g., invalid) if supply power (e.g., supply voltage Vcc) is disconnected from memory device 100. Hereinafter, supply voltage Vcc is referred to as representing some voltage levels; however, they are not limited to a supply voltage (e.g., Vcc) of the memory device (e.g., memory device 100). For example, if the memory device (e.g., memory device 100) has an internal voltage generator (not shown in FIG. 1) that generates an internal voltage based on supply voltage Vcc, such an internal voltage may be used instead of supply voltage Vcc.

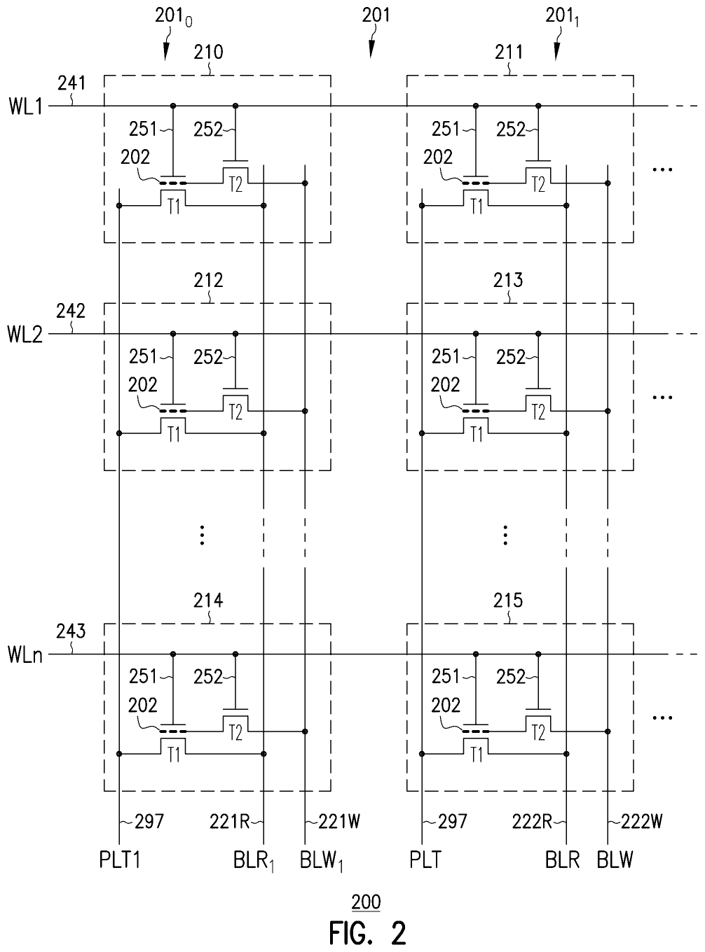

In a physical structure of memory device 100, each of memory cells 102 can include transistors (e.g., two transistors) formed vertically (e.g., stacked on different layers) in different levels over a substrate (e.g., semiconductor substrate) of memory device 100. Memory device 100 can also include multiple levels (e.g., multiple tiers) of memory cells where one level (e.g., one tier) of memory cells can be formed over (e.g., stacked on) another level (e.g., another tier) of additional memory cells. The structure of memory array 101, including memory cells 102, can include the structure of memory arrays and memory cells described below with reference to FIG. 2 through FIG. 7.

As shown in FIG. 1, memory device 100 can include access lines 104 (e.g., “word lines”) and data lines (e.g., bit lines) 105. Memory device 100 can use signals (e.g., word line signals) on access lines 104 to access memory cells 102 and data lines 105 to provide information (e.g., data) to be stored in (e.g., written) or read (e.g., sensed) from memory cells 102.

Memory device 100 can include an address register 106 to receive address information ADDR (e.g., row address signals and column address signals) on lines 107 (e.g., address lines). Memory device 100 can include row access circuitry 108 (e.g., X-decoder) and column access circuitry 109 (e.g., Y-decoder) that can operate to decode address information ADDR from address register 106. Based on decoded address information, memory device 100 can determine which memory cells 102 are to be accessed during a memory operation. Memory device 100 can perform a write operation to store information in memory cells 102, and a read operation to read (e.g., sense) information (e.g., previously stored information) in memory cells 102. Memory device 100 can also perform an operation (e.g., a refresh operation) to refresh (e.g., to keep valid) the value of information stored in memory cells 102. Each of memory cells 102 can be configured to store information that can represent at most one bit (e.g., a single bit having a binary 0 (“0”) or a binary 1 (“1”), or more than one bit (e.g., multiple bits having a combination of at least two binary bits).

Memory device 100 can receive a supply voltage, including supply voltages Vcc and Vss, on lines 130 and 132, respectively. Supply voltage Vss can operate at a ground potential (e.g., having a value of approximately zero volts). Supply voltage Vcc can include an external voltage supplied to memory device 100 from an external power source such as a battery or an alternating current to direct current (AC-DC) converter circuitry.

As shown in FIG. 1, memory device 100 can include a memory control unit 118, which includes circuitry (e.g., hardware components) to control memory operations (e.g., read and write operations) of memory device 100 based on control signals on lines (e.g., control lines) 120. Examples of signals on lines 120 include a row access strobe signal RAS*, a column access strobe signal CAS*, a write-enable signal WE*, a chip select signal CS*, a clock signal CK, and a clock-enable signal CKE. These signals can be part of the signals provided to a DRAM device.

As shown in FIG. 1, memory device 100 can include lines (e.g., global data lines) 112 that can carry signals DQ0 through DQN. In a read operation, the value (e.g., “0” or “1”) of information (read from memory cells 102) provided to lines 112 (in the form of signals DQ0 through DQN) can be based on the values of the signals on data lines 105. In a write operation, the value (e.g., “0” or “1”) of information provided to data lines 105 (to be stored in memory cells 102) can be based on the values of signals DQ0 through DQN on lines 112.

Memory device 100 can include sensing circuitry 103, select circuitry 115, and input/output (I/O) circuitry 116. Column access circuitry 109 can selectively activate signals on lines (e.g., select lines) based on address signals ADDR. Select circuitry 115 can respond to the signals on lines 114 to select signals on data lines 105. The signals on data lines 105 can represent the values of information to be stored in memory cells 102 (e.g., during a write operation) or the values of information read (e.g., sensed) from memory cells 102 (e.g., during a read operation).

I/O circuitry 116 can operate to provide information read from memory cells 102 to lines 112 (e.g., during a read operation) and to provide information from lines 112 (e.g., provided by an external device) to data lines 105 to be stored in memory cells 102 (e.g., during a write operation). Lines 112 can include nodes within memory device 100 or pins (or solder balls) on a package where memory device 100 can reside. Other devices external to memory device 100 (e.g., a hardware memory controller or a hardware processor) can communicate with memory device 100 through lines 107, 112, and 120.

Memory device 100 may include other components, which are not shown in FIG. 1 so as not to obscure the example embodiments described herein. At least a portion of memory device 100 (e.g., a portion of memory array 101) can include structures and operations similar to or the same as any of the memory devices described below with reference to FIG. 2 through FIG. 7.

FIG. 2 shows a schematic diagram of a portion of a memory device 200 including a memory array 201, according to some embodiments described herein. Memory device 200 can correspond to memory device 100 of FIG. 1. For example, memory array 201 can form part of memory array 101 of FIG. 1. As shown in FIG. 2, memory device 200 can include memory cells 210 through 215, which are volatile memory cells (e.g., DRAM cells). For simplicity, similar or identical elements among memory cells 210 through 215 are given the same labels.

Each of memory cells 210 through 215 can include two transistors T1 and T2. Thus, each of memory cells 210 through 215 can be called a 2T memory cell (e.g., 2T gain cell). Each of transistors T1 and T2 can include a field-effect transistor (FET). As an example, Transistor T1 can be a p-channel FET (PFET), and transistor T2 can be an n-channel FET (NFET). Part of transistor T1 can include a structure of a p-channel metal-oxide semiconductor (PMOS) transistor. Thus, transistor T1 can include an operation similar to that of a PMOS transistor. Part of transistor T2 can include an n-channel metal-oxide semiconductor (NMOS). Thus, transistor T2 can include an operation similar to that of a NMOS transistor.

Transistor T1 can include a charge-storage based (e.g., a floating-gate based) structure. As shown in FIG. 2, each of memory cells 210 through 215 can include a charge storage structure 202, which can include the floating gate of transistor T1. Charge storage structure 202 can form the memory element of a respective memory cell among memory cells 210 through 215. Charge storage structure 202 can store charge. The value (e.g., “0” or “1”) of information stored in a particular memory cell among memory cells 210 through 215 can be based on the amount of charge in charge storage structure 202 of that particular memory cell. For example, the value of information stored in a particular memory cell among memory cells 210 through 215 can be “0” or “1” (if each memory cell is configured as a single-bit memory cell) or “00”, “01”, “10”, “11” (or other multi-bit values) if each memory cell is configured as a multi-bit memory cell.

As shown in FIG. 2, transistor T2 (e.g., the channel region of transistor T2) of a particular memory cell among memory cells 210 through 215 can be electrically coupled to (e.g., directly coupled to (contacting)) charge storage structure 202 of that particular memory cell. Thus, a circuit path (e.g., current path) can be formed directly between transistor T2 of a particular memory cell and charge storage structure 202 of that particular memory cell during an operation (e.g., a write operation) of memory device 200. During a write operation of memory device 200, a circuit path (e.g., current path) can be formed between a respective data line (e.g., data line 221W or 222W) and charge storage structure 202 of a particular memory cell through transistor T2 (e.g., through the channel region of transistor T2) of the particular memory cell.

Memory cells 210 through 215 can be arranged in memory cell groups 201₀ and 201₁. FIG. 2 shows two memory cell groups (e.g., 201₀ and 201₁) as an example. However, memory device 200 can include more than two memory cell groups. Memory cell groups 201₀ and 201₁ can include the same number of memory cells. For example, memory cell group 201₀ can include memory cells 210, 212, and 214, and memory cell group 201₁ can include memory cells 211, 213, and 215. FIG. 2 shows three memory cells in each of memory cell groups 201₀ and 201₁ as an example. The number of memory cells in memory cell groups 201₀ and 201₁ can be different from three.

Memory device 200 can perform a write operation to store information in memory cells 210 through 215, and a read operation to read (e.g., sense) information from memory cells 210 through 215. Memory device 200 can be configured to operate as a DRAM device. However, unlike some conventional DRAM devices that store information in a structure such as a container for a capacitor, memory device 200 can store information in the form of charge in charge storage structure 202 (which can be a floating gate structure). As mentioned above, charge storage structure 202 can be the floating gate of transistor T1.

As shown in FIG. 2, memory device 200 can include access lines (e.g., word lines) 241, 242, and 243 that can carry respective signals (e.g., word line signals) WL1, WL2, and WLn. Access lines 241, 242, and 243 can be used to access both memory cell groups 201₀ and 201₁. In the physical structure of memory device 200, each of access lines 241, 242, and 243 can be structured as at least one conductive line (one conductive line or multiple conductive lines can be electrically coupled (e.g., shorted) to each other). Access lines 241, 242, and 243 can be selectively activated (e.g., activated one at a time) during an operation (e.g., read or write operation) of memory device 200 to access a selected memory cell (or selected memory cells) among memory cells 210 through 215. A selected memory cell can be referred to as a target memory cell. In a read operation, information can be read from a selected memory cell (or selected memory cells). In a write operation, information can be stored information in a selected memory cell (or selected memory cells).

As shown in FIG. 2 transistors T1 and T2 can have gates 251 and 252, respectively. The gate (e.g., gate 251 or 252) of each of transistors T1 and T2 can be part of a respective access line (e.g., a respective word line). As shown in FIG. 2, the gate (e.g., gate 251 or 252) of each of transistors T1 and T2 of memory cell 210 can be part of access line 241. The gate (e.g., gate 251 or 252) of each of transistors T1 and T2 of memory cell 211 can be part of access line 241. For example, in the physical structure of memory device 200, four different portions of a conductive material (e.g., four different portions of continuous piece of metal or polysilicon) that forms access line 241 can form four gates that include gates 251 and 252 of respective transistors T1 and T2 of memory cell 210 and gates 251 and 252 of respective transistors T1 and T2 of memory cell 211.

At access line 242, the gate (e.g., gate 251 or 252) of each of transistors T1 and T2 of memory cell 212 can be part of access line 242. The gate (e.g., gate 251 or 252) of each of transistors T1 and T2 of memory cell 213 can be part of access line 242. For example, in the physical structure of memory device 200, four different portions of a conductive material (e.g., four different portions of a continuous piece of metal or polysilicon) that forms access line 242 can form four gates that include gates 251 and 252 of respective transistors T1 and T2 of memory cell 212 and gates 251 and 252 of respective transistors T1 and T2 of memory cell 213.

At access line 243, the gate (e.g., gate 251 or 252) of each of transistors T1 and T2 of memory cell 214 can be part of access line 243. The gate (e.g., gate 251 or 252) of each of transistors T1 and T2 of memory cell 215 can be part of access line 243. For example, in the physical structure of memory device 200, four different portions of a conductive material (e.g., four different portions of a continuous piece of metal or polysilicon) that forms access line 243 can form four gates that include gates 251 and 252 of respective transistors T1 and T2 of memory cell 214 and gates 251 and 252 of respective transistors T1 and T2 of memory cell 215.

In this description, a material can include a single material or a combination of multiple materials. A conductive material can include a single conductive material or a combination of multiple conductive materials.

Memory device 200 can include data lines (e.g., read bit lines) 221R and 222R that can carry respective signals (e.g., read bit line signals) BLR₁ and BLR, and data lines (e.g., write bit lines) 221W and 222W that can carry respective signals (e.g., write bit line signals)) BLW₁ and BLW. Each of data lines 221R, 221W, 222R, and 222W can be part of a conductive structure (e.g., a conductive line). During a read operation, memory device 200 can use data line 221R to obtain information read (e.g., sense) from a selected memory cell of memory cell group 201₀, and data line 222R to obtain information read (e.g., sense) from a selected memory cell of memory cell group 201₁. During a write operation, memory device 200 can use data line 221W to provide information to be stored in a selected memory cell of memory cell group 201₀, and data line 222W to provide information to be stored in a selected memory cell of memory cell group 201₁.

Memory device 200 can include connections (e.g., plates) 297 coupled to respective memory cells 210 through 215. Connections 297 can be associated with (e.g., used to carry) respective signals PLT1 and PLT. Each of connections 297 can be part of a conductive structure (e.g., a conductive plate). In operation, connections 297 can be coupled to a voltage (e.g., a positive voltage) or alternatively to a ground terminal (ground connection) of memory device 200.

As shown in FIG. 2, transistor T1 (e.g., the channel region of transistor T1) of a particular memory cell among memory cells 210 through 215 can be electrically coupled to (e.g., directly coupled to) connection 297 and electrically coupled to (e.g., directly coupled to) a respective data line (e.g., data line 221R or 222R). Thus, a circuit path (e.g., current path) can be formed between a respective data line (e.g., data line 221R or 222R) and a connection 297 through transistor T1 of a selected memory cell during an operation (e.g., a read operation) performed on the selected memory cell.

Memory device 200 can include read paths (e.g., circuit paths). Information read from a selected memory cell during a read operation can be obtained through a read path coupled to the selected memory cell. In memory cell group 201₀, a read path of a particular memory cell (e.g., 210, 212, or 214) can include a current path (e.g., read current path) through a channel region of transistor T1 of that particular memory cell and data line 221R. In memory cell group 201₁, a read path of a particular memory cell (e.g., 211, 213, or 215) can include a current path (e.g., read current path) through a channel region of transistor T1 of that particular memory cell and data lines 222R. Since transistor T1 can be used in a read path to read information from the respective memory cell during a read operation, transistor T1 can be called a read transistor and the channel region of transistor T1 can be called a read channel region.

Memory device 200 can include write paths (e.g., circuit paths). Information to be stored in a selected memory cell during a write operation can be provided to the selected memory cell through a write path coupled to the selected memory cell. In memory cell group 201₀, a write path of a particular memory cell (e.g., 210, 212, or 214) can include a current path (e.g., write current path) through a channel region of transistor T2 of that particular memory cell and data line 221W. In memory cell group 201₁, a write path of a particular memory cell (e.g., 211, 213, or 215) can include a current path (e.g., a write current path) through a channel region of transistor T2 of that particular memory cell and data line 222W. Since transistor T2 can be used in a write path to store information in a respective memory cell during a write operation, transistor T2 can be called a write transistor and the channel region of transistor T2 can be called a write channel region.

Each of transistors T1 and T2 can have a threshold voltage (Vt). Transistor T1 has a threshold voltage Vt1. Transistor T2 has a threshold voltage Vt2. The values of threshold voltages Vt1 and Vt2 can be different (unequal values). For example, the value of threshold voltage Vt2 can be greater than the value of threshold voltage Vt1. The difference in values of threshold voltages Vt1 and Vt2 allows reading (e.g., sensing) of information stored in charge storage structure 202 in transistor T1 on the read path during a read operation without affecting (e.g., without turning on) transistor T2 on the write path (e.g., path through transistor T2). This can prevent leaking of charge (e.g., during a read operation) from charge storage structure 202 through transistor T2 of the write path.

In a structure of memory device 200, transistors T1 and T2 can be formed (e.g., engineered) such that threshold voltage Vt1 of transistor T1 can be less than zero volts (e.g., Vt1<0V) regardless of the value (e.g., “0” or “1”) of information stored in charge storage structure 202 of transistor T1, and Vt1<Vt2. Charge storage structure 202 can be in state “0” when information having a value of “0” is stored in charge storage structure 202. Charge storage structure 202 can be in state “1” when information having a value of “1” is stored in charge storage structure 202. Thus, in this structure, the relationship between the values of threshold voltages Vt1 and Vt2 can be expressed as follows, Vt1 for state “0”<Vt1 for state “1”<0V, and Vt2=0V (or alternatively Vt2>0V).

In an alternative structure of memory device 200, transistors T1 and T2 can be formed (e.g., engineered) such that Vt1 for state “0”<Vt1 for state “1”, where Vt1 for state “0”<0V (or alternatively Vt1 for state “0”=0V), Vt1 for state “1”>0V, and Vt1<Vt2.

In another alternative structure, transistors T1 and T2 can be formed (e.g., engineered) such that Vt1 for state “0”<Vt1 for state “1”, where Vt1 for state “0”=0V (or alternatively Vt1 for state “0”>0V), and Vt1<Vt2.

During a read operation of memory device 200, only one memory cell of the same memory cell group can be selected one at a time to read information from the selected memory cell. For example, memory cells 210, 212, and 214 of memory cell group 201₀ can be selected one at a time during a read operation to read information from the selected memory cell (e.g., one of memory cells 210, 212, and 214 in this example). In another example, memory cells 211, 213, and 215 of memory cell group 201₁ can be selected one at a time during a read operation to read information from the selected memory cell (e.g., one of memory cells 211, 213, and 215 in this example).

During a read operation, memory cells of different memory cell groups (e.g., memory cell groups 201₀ and 201₁) that share the same access line (e.g., access line 241, 242, or 243) can be concurrently selected (or alternatively can be sequentially selected). For example, memory cells 210 and 211 can be concurrently selected during a read operation to read (e.g., concurrently read) information from memory cells 210 and 211. Memory cells 212 and 213 can be concurrently selected during a read operation to read (e.g., concurrently read) information from memory cells 212 and 213. Memory cells 214 and 215 can be concurrently selected during a read operation to read (e.g., concurrently read) information from memory cells 214 and 215.

The value of information read from the selected memory cell of memory cell group 201₀ during a read operation can be determined based on the value of a current detected (e.g., sensed) from a read path (described above) that includes data line 221R, transistor T1 of the selected memory cell (e.g., memory cell 210, 212, or 214), and connection 297. The value of information read from the selected memory cell of memory cell group 201₁ during a read operation can be determined based on the value of a current detected (e.g., sensed) from a read path that includes data line 222R, transistor T1 of the selected memory cell (e.g., memory cell 211, 213, or 215), and connection 297.

Memory device 200 can include detection circuitry (not shown) that can operate during a read operation to detect (e.g., sense) a current (e.g., current I1, not shown) on a read path that includes connection 297 and data line 221R, and detect a current (e.g., current I2, not shown) on a read path that includes connection 297 and data line 222R. The value of the detected current can be based on the value of information stored in the selected memory cell. For example, depending on the value of information stored in the selected memory cell of memory cell group 201₀, the value of the detected current (e.g., the value of current I1) between connection 297 and data line 221R can be zero or greater than zero. Similarly, depending on the value of information stored in the selected memory cell of memory cell group 201₁, the value of the detected current (e.g., the value of current I2) between connection 297 and data line 222R can be zero or greater than zero. Memory device 200 can include circuitry (not shown) to translate the value of detected current into the value (e.g., “0”, “1”, or a combination of multi-bit values) of information stored in the selected memory cell.

During a write operation of memory device 200, only one memory cell of the same memory cell group can be selected at a time to store information in the selected memory cell. For example, memory cells 210, 212, and 214 of memory cell group 201₀ can be selected one at a time during a write operation to store information in the selected memory cell (e.g., one of memory cell 210, 212, and 214 in this example). In another example, memory cells 211, 213, and 215 of memory cell group 201₁ can be selected one at a time during a write operation to store information in the selected memory cell (e.g., one of memory cell 211, 213, and 215 in this example).

During a write operation, memory cells of different memory cell groups (e.g., memory cell groups 201₀ and 201₁) that share the same access line (e.g., access line 241, 242, or 243) can be concurrently selected. For example, memory cells 210 and 211 can be concurrently selected during a write operation to store (e.g., concurrently store) information in memory cells 210 and 211. Memory cells 212 and 213 can be concurrently selected during a write operation to store (e.g., concurrently store) information in memory cells 212 and 213. Memory cells 214 and 215 can be concurrently selected during a write operation to store (e.g., concurrently store) information in memory cells 214 and 215.

Information to be stored in a selected memory cell of memory cell group 201₀ during a write operation can be provided through a write path (described above) that includes data line 221W and transistor T2 of the selected memory cell (e.g., memory cell 210, 212, or 214). Information to be stored in a selected memory cell of memory cell group 201₁ during a write operation can be provided through a write path (described above) that includes data line 222W and transistor T2 of the selected memory cell (e.g., memory cell 211, 213, or 215). As described above, the value (e.g., binary value) of information stored in a particular memory cell among memory cells 210 through 215 can be based on the amount of charge in charge storage structure 202 of that particular memory cell.

In a write operation, the amount of charge in charge storage structure 202 of a selected memory cell can be changed (to reflect the value of information stored in the selected memory cell) by applying a voltage on a write path that includes transistor T2 of that particular memory cell and the data line (e.g., data line 221W or 222W) coupled to that particular memory cell. For example, a voltage having one value (e.g., 0V) can be applied on data line 221W (e.g., provide 0V to signal BL1) if information to be stored in a selected memory cell among memory cells 210, 212, and 214 has one value (e.g., “0”). In another example, a voltage having another value (e.g., a positive voltage) can be applied on data line 221W (e.g., provide a positive voltage to signal BL1) if information to be stored in a selected memory cell among memory cells 210, 212, and 214 has another value (e.g., “1”). Thus, information can be stored (e.g., directly stored) in charge storage structure 202 of a particular memory cell by providing the information to be stored (e.g., in the form of a voltage) on a write path (that includes transistor T2) of that particular memory cell.

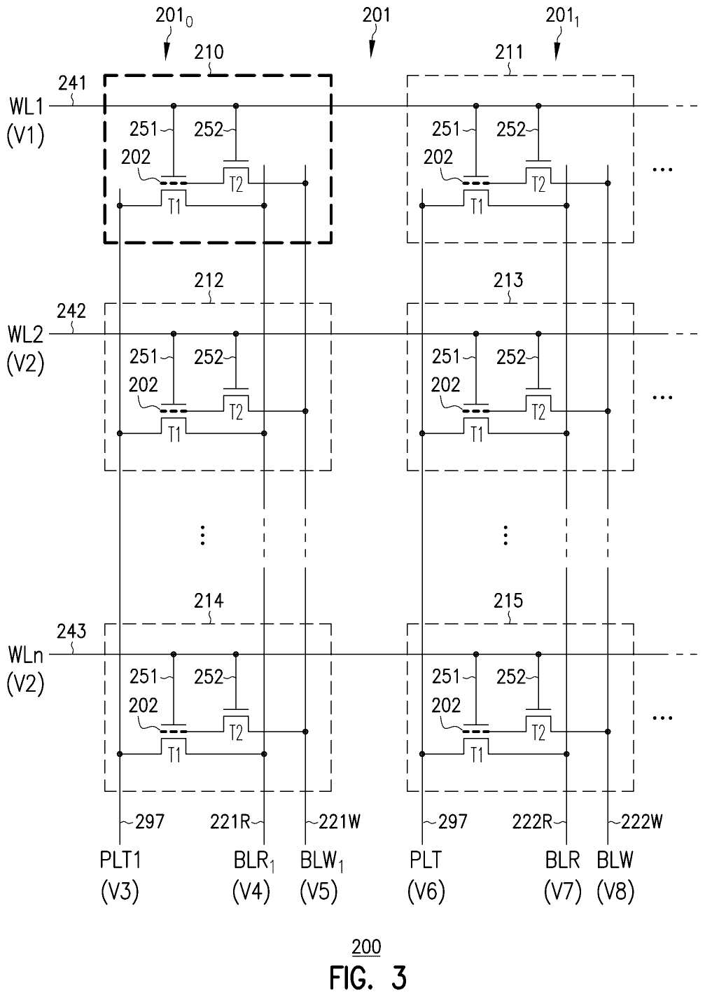

FIG. 3 shows memory device 200 of FIG. 2 including example voltages V1 through V8 used during a read operation of memory device 200, according to some embodiments described herein. The example of FIG. 3 assumes that memory cell 210 is a selected memory cell (e.g., target memory cell) during a read operation to read (e.g., to sense) information stored (e.g., previously stored) in memory cell 210. Memory cells 211 through 215 are assumed to be unselected memory cells. This means that memory cells 211 through 215 are not accessed and information stored in memory cells 211 through 215 is not read while information is read from memory cell 210 in the example of FIG. 3. In this example, access line 241 can be called a selected access line (e.g., selected word line), which is the access line associated with (e.g., coupled to) selected memory cells (e.g., memory cell 210 in this example). In this example, access lines 242 and 243 can be called unselected access lines (e.g., unselected word line), which are the access lines associated with (e.g., coupled to) unselected memory cells (e.g., memory cells 211 through 215 in this example).

In FIG. 3, voltages V1 through V8 can represent different voltages applied to respective access lines 241, 242, and 243; data lines 221R, 221W, 222R, 222W; and connections 297 during a read operation of memory device 200. In the read operation shown in FIG. 3, voltage V1 can have a value (voltage value) to turn on transistor T1 of memory cell 210 (a selected memory cell in this example) and turn off (or keep off) transistor T2 of memory cell 210. This allows information to be read from memory cell 210. Voltages V2, V3, and V5 through V8 can have values, such that transistors T1 and T2 of each of memory cells 211 through 215 (unselected memory cells in this example) are turned off (e.g., kept off). Voltage V4 can have a value, such that a current (e.g., read current) may be formed on a read path that includes data line 221R and connection 297 (coupled to memory cell 210) and transistor T1 of memory cell 210. This allows a detection of current on the read path coupled to memory cell 210. A detection circuitry (not shown) of memory device 200 can operate to translate the value of detected current (during reading of information from a selected memory cell) into the value (e.g., “0”, “1”, or a combination of multi-bit values) of information read from the selected memory cell. In the example of FIG. 3, the value of detected current on data line 221R and connection 297 can be translated into the value of information read from memory cell 210.

In the read operation shown in FIG. 3, the voltages applied to respective access lines 241, 242, and 243 can cause transistors T1 and T2 of each of memory cells 211 through 215, except transistor T1 of memory cell 210, to turn off (or to remain turned off). Transistor T1 of memory cell 210 may or may not turn on, depending on the value of the threshold voltage Vt1 of transistor T1 of memory cell 210. For example, if transistor T1 of each of memory cells (e.g., 210 through 215) of memory device 200 is configured (e.g., structured) such that the threshold voltage of transistor T1 is less than zero (e.g., Vt1<0V) regardless of the value (e.g., the state) of information stored in a respective memory cell 210, then transistor T1 of memory cell 210 in this example can turn on and conduct a current between data line 221R and connection 297 (through transistor T1 of memory cell 210). Memory device 200 can determine the value of information stored in memory cell 210 based on the value of the current between data line 221R and connection 297. As described above, memory device 200 can include detection circuitry to measure the value of current between data line 221R and connection 297 (or between data line 222R and connection 297) during a read operation.

As an example read operation associated with FIG. 3, voltages V1 and V2 can have values of 0.5V and 0V, respectively. Voltages V3 and V4 have values of 0.5V and 0V, respectively. Each of voltages V5 and V8 have values of 0V. Each of voltages V6 and V7 have values of 0V. The values of the voltages in this example are examples. Different values may be used. In another example read operation associated with FIG. 3, data lines 222R and connection 297 associated with signal PLT can be placed in a “FLOAT” condition. Placing a particular conductive line (e.g., data line 222R) in a FLOAT condition during a particular operation can include allowing the potential on that particular conductive line to vary or to “float” (e.g., by not coupling that particular conductive line to a fixed potential (e.g., ground or other voltages)). In the example read operation of FIG. 3, each of data lines 222R and connection 297 associated with signal PLT in FIG. 3 can be placed in a FLOAT condition by, for example, decoupling each of data lines 222R and connection 297 associated with signal PLT from ground or from a fixed positive voltage source. This allows the potential on each of data lines 222R and connection 297 associated with signal PLT to vary (e.g., to “float”) during the operation of reading information from memory cell 210 (selected memory cell in this example).

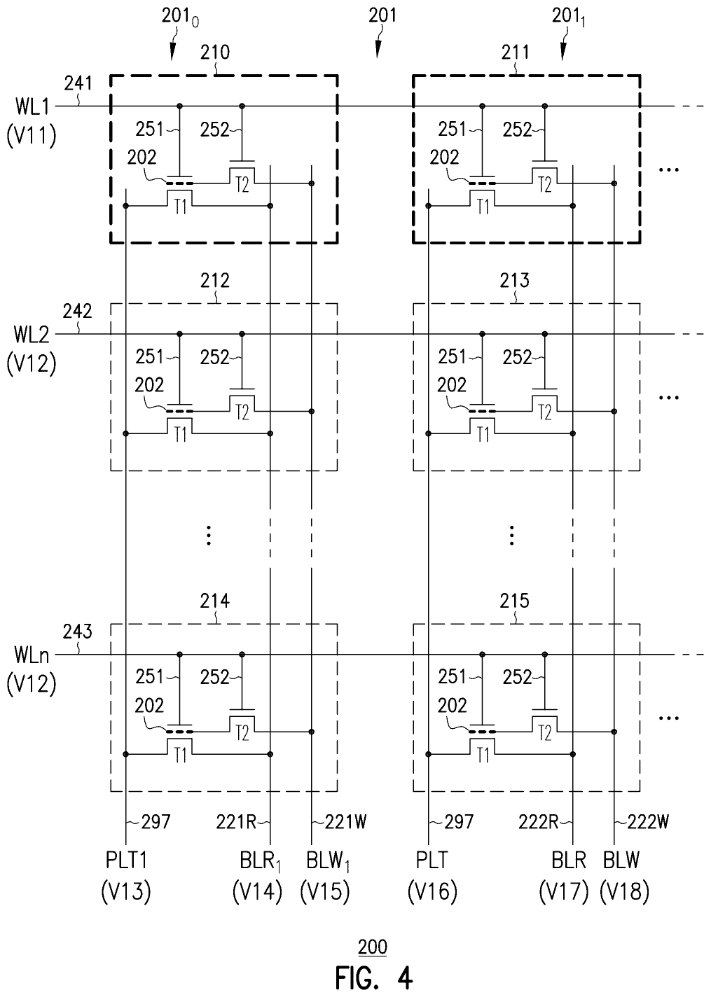

FIG. 4 shows memory device 200 of FIG. 2 including example voltages V11 through V18 used during a write operation of memory device 200, according to some embodiments described herein. The example of FIG. 4 assumes that memory cells 210 and 211 are selected memory cell (e.g., target memory cells) during a write operation to store information in memory cells 210 and 211. Memory cells 212 through 215 are assumed to be unselected memory cells. This means that memory cells 212 through 215 are not accessed and information stored is not to be stored in memory cells 212 through 215 while information is stored in memory cells 210 and 211 in the example of FIG. 4.

In FIG. 4, voltages V11 through V18 can represent different voltages applied to respective access lines 241, 242, and 243; data lines 221R, 221W, 222R, and 222W; and connections 297 during a write operation of memory device 200.

In a write operation of memory device 200 of FIG. 4, voltage V12 can have a value, such that transistors T1 and T2 of each of memory cells 212 through 215 (unselected memory cells in this example) are turned off (e.g., kept off). Voltages V11 can have a value to turn on transistor T2 of each of memory cells 210 and 211 (selected memory cells in this example) and form a write path between charge storage structure 202 of memory cell 210 and data line 221W, and a write path between charge storage structure 202 of memory cell 211 and data line 222W. A current (e.g., write current) may be formed between charge storage structure 202 of memory cell 210 and data line 221W. This current can affect (e.g., change) the amount of charge on charge storage structure 202 of memory device 200 to reflect the value of information to be stored in memory cell 210. A current (e.g., another write current) may be formed between charge storage structure 202 of memory cell 211 and data line 222W. This current can affect (e.g., change) the amount of charge on charge storage structure 202 of memory device 200 to reflect the value of information to be stored in memory cell 211.

In the example write operation of FIG. 4, the value of voltage V15 may cause charge storage structure 202 of memory cell 210 to discharge or to be charged, such that the resulting charge (e.g., charge remaining after the discharge or charge action) on charge storage structure 202 of memory cell 210 can reflect the value of information stored in memory cell 210. Similarly, the value of voltage V18 in this example may cause charge storage structure 202 of memory cell 211 to discharge or to be charged, such that the resulting charge (e.g., charge remaining after the discharge or charge action) on charge storage structure 202 of memory cell 211 can reflect the value of information stored in memory cell 211.

As an example write operation associated with FIG. 4, voltages V11 and V12 can have values of 2.5V and 0V, respectively. The value of each of voltages V15 and V18 can be less than, equal to, or greater than the value of voltage V5, depending on the value (e.g., “0” or “1”) of information to be stored in memory cells 210 and 211. The specific values of voltages used in this description are only example values. Different values may be used.

Data lines 221R and 222R and connections 297 can be placed in a “float” connection, such that voltages V13, V14, V16, and V17 on respective data lines 221R and 222R, and connections 297, may be unfixed at particular values.

The values of voltages V15 and V18 can be the same or different, depending on the value (e.g., “0” or “1”) of information to be stored in memory cells 210 and 211. For example, the values of voltages V15 and V18 can be the same (e.g., V15=V18) if the memory cells 210 and 211 are to store information having the same value. As an example, V15=V18=0V, and V11=2.5V if information to be stored in each memory cell 210 and 211 is “0”, and V15=V18=1V to 3V, and V11=2.5V if information to be stored in each memory cell 210 and 211 is “1”.

In another example, the values of voltages V15 and V18 can be different from each other (e.g., V15/V18) if the memory cells 210 and 211 are to store information having different values. As an example, V15=0V, V18=1V to 3V, and V11=2.5V if information to be stored in memory cell 210 is “0” and information to be stored in memory cell 211 is “1”. As another example, V15=1V to 3V, V18=0V, and V11=2.5V if information to be stored in memory cell 210 is “1” and information to be stored in memory cell 211 is “0”.

The range of voltage of 1V to 3V is used here as an example. A different range of voltage can be used. Further, instead of 0V, a positive voltage (e.g., V15>0V or V18>0V) may be applied to that particular write data line (e.g., data line 221W or 222W) for storing information having a value of “0” to the memory cell (e.g., memory cell 210 or 211) coupled to that particular write data line.

The example write operation of FIG. 4 assumes that memory cells 210 and 211 are selected (e.g., concurrently selected) to store (e.g., concurrently store) information. In another write operation, either memory cell 210 or memory cell 211 can be selected to store information. For example, in another write operation, memory cell 210 can be selected and memory cells 211 through 215 can be unselected memory cells. In such a write operation, voltage V18 can be applied with a voltage (e.g., a write inhibit voltage (e.g., V18=V11)) such that memory cell 211 is inhibited from storing information when information is stored in memory cell 210 (selected memory cell). Similarly, if memory cell 211 is selected to store information and memory cells 210 and 212 through 215 are unselected, then voltage V15 can be applied with a voltage (e.g., a write inhibit voltage (e.g., V15=V11)) such that memory cell 210 is inhibited from storing information when information is stored in memory cell 211 (selected memory cell).

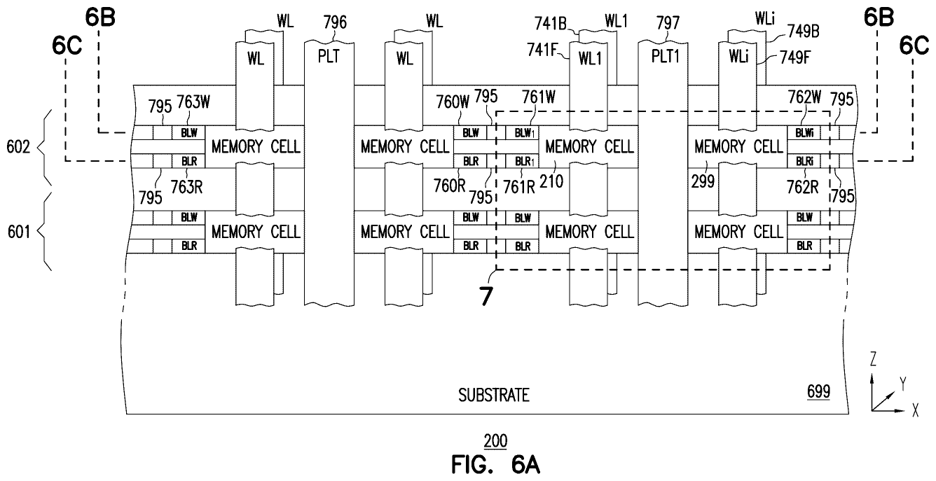

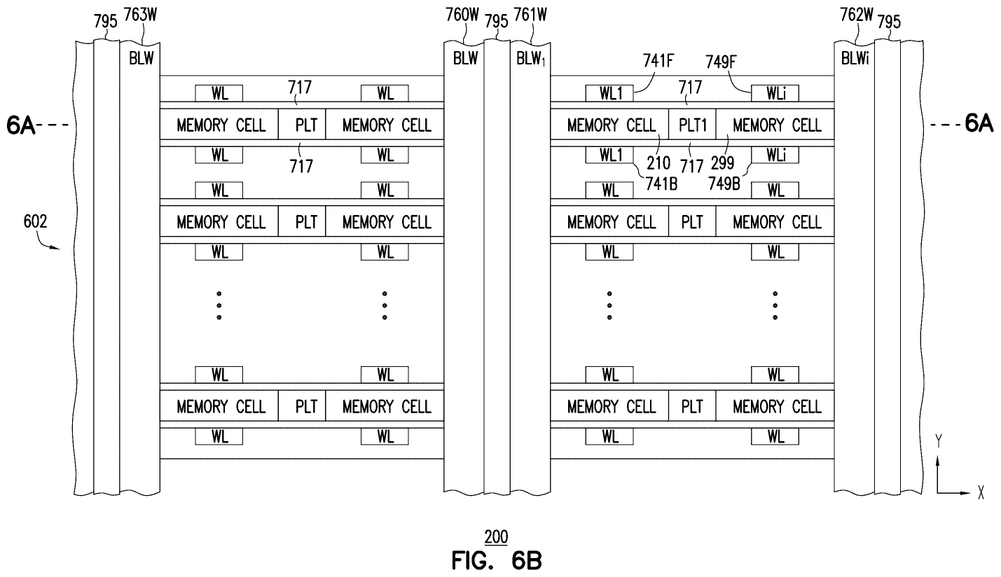

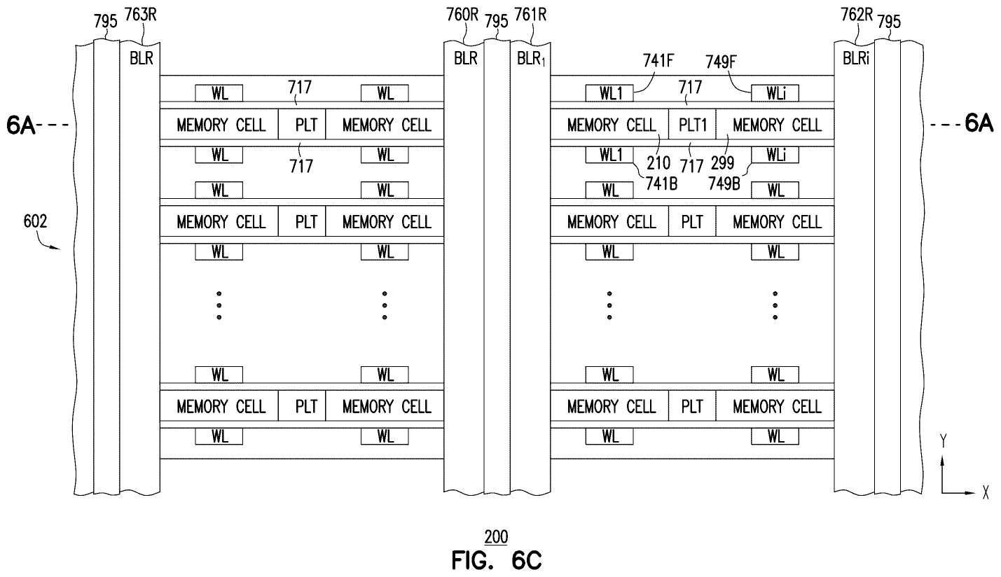

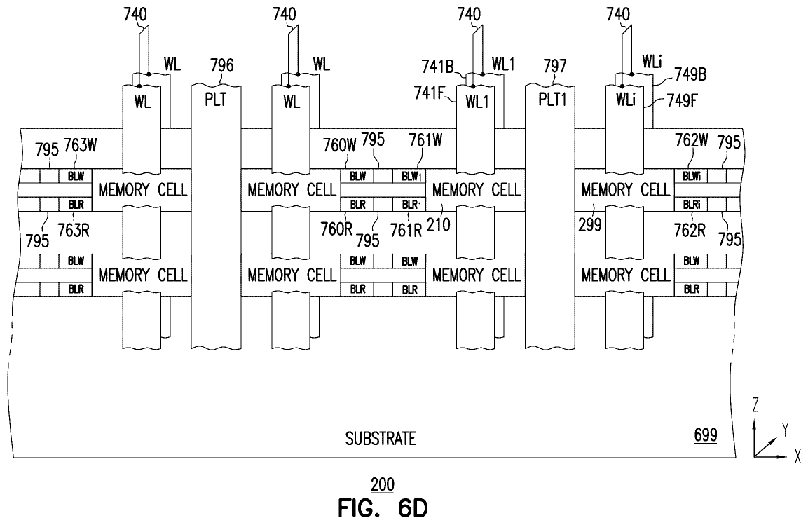

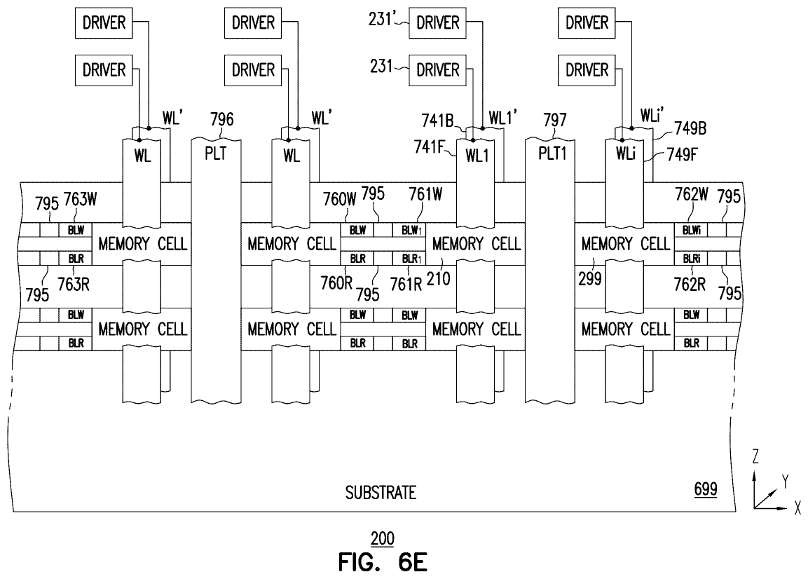

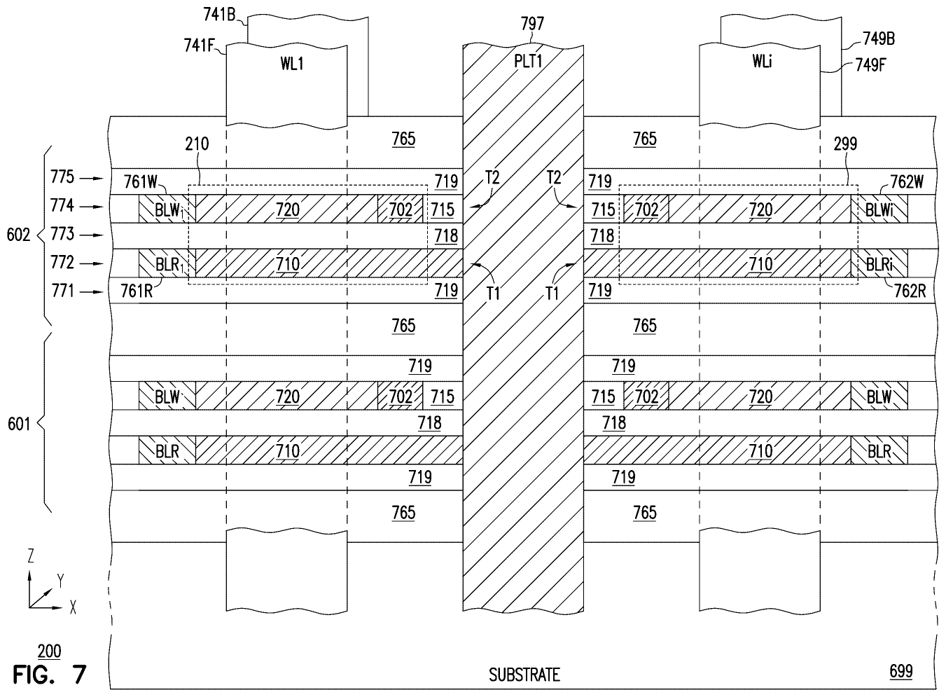

Memory device 200 described above with reference to FIG. 2 through FIG. 4 can have a structure (e.g., a 2-T memory structure) of the memory device 200 described below with reference to FIG. 6A through FIG. 7.

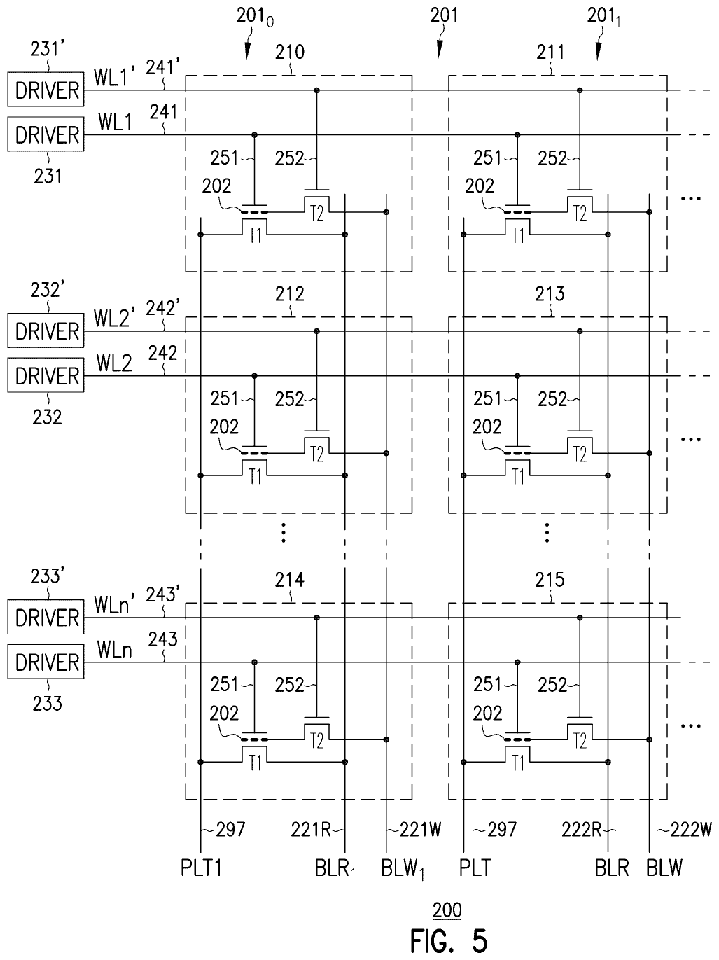

FIG. 5 shows memory device 200 of FIG. 2, including separate access lines (e.g., separate word lines) for transistors T1 and T2 of each memory cell, according to some embodiments described herein. Memory device 200 of FIG. 5 can be a variation of memory device 200 of FIG. 2. As shown in FIG. 5, memory device 200 can include access lines (e.g., word lines) 241, 241′, 242, 242′, 243, and 243′ that can carry respective signals (e.g., word line signals) WL1, WL1′, WL2, WL2′, WLn, and WLn′. Access lines 241, 241′, 242, 242′, 243, and 243′ can be electrically separated from each other. Each memory cell can be associated with two access lines (e.g., read access line and write access line).

Access lines 241, 242, and 243 can be read access lines. Access lines 241, 242, and 243 can be used to selectively turn on a respective transistor T1 (e.g., read transistor) of a selected memory cell (or selected memory cells) during a read operation to read information from the selected memory cell (or selected memory cells). Access lines 241, 242, and 243 can also be used to turn off a respective transistor T1 of a selected memory cell (or selected memory cells) during a write operation performed on a selected memory cell (or selected memory cells).

Access lines 241′, 242′, and 243′ can be called write access lines. Access lines 241′, 242′, and 243′ can be used to selectively turn on a respective transistor T2 (e.g., write transistor) of a selected memory cell (or selected memory cells) during a write operation to store information in the selected memory cell (or selected memory cells). Access lines 241′, 242′, and 243′ can also be used to turn off a respective transistor T2 of a selected memory cell (or selected memory cells) during a read operation performed on a selected memory cell (or selected memory cells).

As shown in FIG. 5, each of gates 251 and 252 of respective transistors T1 and T2 can be electrically coupled to a respective access line. In the structure of memory device 200 (see FIG. 6A through FIG. 7), each of gates 251 and 252 can be formed from a portion (e.g., portion of the material) of a respective access line among access lines 241, 241′, 242′, 242, 243, and 243′. As described above with reference to FIG. 2, access lines (e.g., access lines 241 and 241′) associated with a memory cell (e.g., memory cell 210) can be electrically separated from each other. Thus, gate 251 of transistor T1 and gate 252 of transistor T2 of a memory cell (e.g., memory cell 210) are also electrically separated from each other.

In memory device 200 of FIG. 5 gates 251 of different transistors T1 of memory cells associated with the same access line (e.g., a read access line) can be formed from different portions of the conductive material that forms that access line. Gates 252 of different transistors T2 of memory cells associated with the same access line (e.g., a write access line) can be formed from different portions of the conductive material that forms that access line.

For example, as shown in FIG. 5, gates 251 of respective transistors T1 of memory cells 210 and 211 can be formed from two respective portions of a conductive material (or materials) that forms access line 241. Gates 252 of respective transistors T2 of memory cells 210 and 211 can be formed from two respective portions of a conductive material (or materials) that forms access line 241′.

Gates 251 of respective transistors T1 of memory cells 212 and 213 can be formed from two respective portions of a conductive material (or materials) that forms access line 242. Gates 252 of respective transistors T2 of memory cells 212 and 213 can be formed from two respective portions of a conductive material (or materials) that forms access line 242′.

Gates 251 of respective transistors T1 of memory cells 214 and 215 can be formed from two respective portions of a conductive material (or materials) that forms access line 243. Gates 252 of respective transistors T2 of memory cells 214 and 215 can be formed from two respective portions of a conductive material (or materials) that forms access line 243′.

Access lines 241, 241′, 242, 242′, 243, and 243′ can be used to access both memory cell groups 201₀ and 201₁. Each of access lines 241, 241′, 242, 242′, 243, and 243′ can be structured as a conductive line, which can be driven (e.g., activated) by a separate driver (described below).

Memory device 200 can include drivers 231, 231′, 232, 232′, 233, and 233′ coupled to access lines 241, 241′, 242, 242′, 243, and 243′ respectively. Drivers 231, 232, and 233 can be called read drivers and can be used to selectively drive (e.g., activate) access lines 241, 242, and 243, respectively, during a read operation. Drivers 231′, 232′, and 233′ can be called write drivers and can be used to selectively drive (e.g., activate) access lines 241′, 242′, and 243′, respectively, during a write operation.

Drivers 231, 231′, 232, 232′, 233, and 233′ can be coupled to access lines 241, 241′, 242, 242′, 243, and 243′ respectively. Drivers can be complementary metal oxide semiconductor (CMOS) drivers or other types of drivers that can operate to provide (e.g., drive) signals WL1, WL1′, WL2, WL2′, WLn, and WLn′ associated with access lines 241, 241′, 242, 242′, 243, and 243′, respectively. Signals WL1, WL1′, WL2, WL2′, WLn, and WLn′ can be provided (e.g., biased) with different voltages depending on which operation (e.g., read or write operation) memory device 200 performs.

Drivers 231, 231′, 232, 232′, 233, and 233′ can be configured to drive access lines 241, 241′, 242, 242′, 243, and 243′, respectively, one at a time during an operation (e.g., read or write operation) of memory device 200 to access a selected memory cell (or selected memory cells) among memory cells 210 through 215. A selected cell can be referred to as a target cell. In a read operation, information can be read from a selected memory cell (or selected memory cells). In a write operation, information can be stored in a selected memory cell (or selected memory cells).

In an operation (e.g., read or write performed on a selected memory cell, the drivers coupled to the access lines (selected access lines) associated with the selected memory cell can apply different voltages on the selected access lines (the conductive regions of the selected access lines). For example, during an operation (e.g., a read operation) of reading information from memory cell 210, driver 231 can apply a voltage on line 241 to turn on transistor T1 of memory cell 210, and driver 231′ can apply another voltage on line 241′ to turn off transistor T2 of memory cell 210. In another example, during an operation (e.g., a write operation) of storing information in memory cell 210, driver 231 can apply a voltage on line 241 to turn off transistor T1 of memory cell 210, and driver 231′ can apply another voltage on line 241′ to turn on transistor T2 of memory cell 210. Including separate drivers (e.g., drivers 231 and 231′) for the access lines (e.g., access lines 241 and 241′) associated with a memory cell (e.g., memory cell 210) can improve operation of memory device 200. For example, separate drivers can allow turning off (e.g., fully turning off) of either transistor T1 or T2 of a selected memory cell in a particular operation (e.g., read or write operation) to improve control of current (e.g., read current or write current) associated with the selected memory cell.

The structure of memory device 200 described above with reference to FIG. 2 through FIG. 5 is described below with reference to FIG. 6A through FIG. 7.

For simplicity, detailed description of the same elements of memory device 200 is not repeated in the description of FIG. 6A through FIG. 7. Some of the memory cells and associated data lines and access lines of memory device 200 schematically shown in FIG. 2 are not shown in FIG. 6A through FIG. 7. FIG. 6A through FIG. 7 also show some of the memory cells and associated data lines and access lines of memory device 200 that are not schematically shown in FIG. 2. For simplicity and ease of viewing, cross-sectional lines (e.g., hatch lines) are omitted from most of the elements shown in FIG. 6A through FIG. 7 and other figures described herein. Some elements of memory device 200 may be omitted from a particular figure of the drawings so as to not obscure the description of the element (or elements) being described in that particular figure. The dimensions (e.g., physical structures) of the elements shown in the drawings described herein are not scaled.

FIG. 6A shows a structure of memory device 200 including a substrate 699 and tiers 601 and 602 located (e.g., stacked) one over another over substrate 699, according to some embodiments described herein. FIG. 6A shows two tiers 601 and 602 of memory device 200 as an example. However, memory device 200 includes numerous tiers (e.g., up to 100 tiers or more than 100 tiers).

The X, Y, and Z directions shown in FIG. 6A can represent the directions corresponding to a three-dimensional (3-D) structure of memory device 200. For simplicity, FIG. 6A only shows the portion of memory device 200 with respect to the X-Z direction. The Z-direction (e.g., vertical direction) is a direction perpendicular to (e.g., outward from) substrate 699. The Z-direction is also perpendicular to (e.g., extended vertically from) the X-direction and the Y-direction. The X-direction and Y-direction are perpendicular to each other. Top views of memory device 200 in the X-Y directions (e.g., X-Y plan view) along line 6B-6B and 6C-6C are shown FIG. 6B and FIG. 6C, respectively. A portion labeled “7” in FIG. 6A is shown in detail in FIG. 7.

In FIG. 6A, substrate 699 can be a semiconductor substrate (e.g., silicon-based substrate) or other types of substrates. As shown in FIG. 6A, each of tiers 601 and 602 can have its own memory cells (labeled “MEMORY CELL”). Thus, tiers 601 and 602 can be call memory cell tiers 601 and 602.

FIG. 6A shows some of the access lines (e.g., word lines) of memory device 200 such as the access lines associated with signals WL, WL1, and WLi. For simplicity, the term “the access lines” (without accompanying labels) refers to of the access lines associated with signals WL, WL1, and WLi in FIG. 6A and access lines (e.g., word lines) in other figures (e.g., FIG. 6B through FIG. 7) that are similar to the access lines associated with signals WL, WL1, and WLi in FIG. 6A.

In FIG. 6A, the access lines associated with signals WL, WL1, WLi are shown in partial cut-away view to show some portions of the underlying memory cells adjacent these access lines. As shown in FIG. 6A, each of the access lines associated with signals WL, WL1, WLi can be a separate strip (e.g., strip of conductive material) having length in the Z-direction, which is the same as the direction from one tier (e.g., tier 601) to another tier (e.g., tier 602) of memory device 200. Thus, in memory device, the access lines of memory device 200 can extend (have lengths) in the direction from one tier to another tier of memory device 200.

The access lines associated with signals WL, WL1, WLi can be separated (electrically separated) from each other in the X-direction. As shown in FIG. 6A, the memory cells of the same tier (e.g., tier 602) can be arranged (spaced apart from each other) in the X-direction and arranged (spaced apart from each other) the Y-direction. The memory cells (e.g., neighbor memory cells) in the X-direction may not share an access line (e.g., may not share a word line). For example, memory cell 210, which is a neighbor of (e.g., adjacent) memory cell 299 and is located at a distance from memory cell 299 in the X-direction, may not share the access line associated with signal WL1 with memory cell 299 in the X-direction. Memory cells of different tiers (e.g., tiers 601 and 602) of memory device 200 may share access lines. For example, the memory cells of tier 601 may share access lines with the memory cells of tier 602.

As shown in FIG. 6A, each memory cell can be associated with two respective portions of the access lines (e.g., front and back access lines). For example, memory cell 210 can be associated with two respective portions of the access lines associated with signals WL1. In another example, memory cell 299 can be associated with two respective portions of the access lines associated with signals WLi.

As shown in FIG. 6A, each memory cell can be adjacent and between two conductive regions (e.g., front and back conductive regions) of an access line. For example, the access line associated with signal WL1 can include a conductive region (e.g., front conductive region) 741F and a conductive region (e.g., back conductive region) 741B. Conductive regions 741F and 741B can be part of access line 241 (FIG. 2) of memory device 200. Conductive regions 741F and 741B are opposite from each other in the Y-direction. For example, conductive region 741F can be located on one side (e.g., front side in the Y-direction) of memory cell 210. Conductive region 741B can be located on another side (e.g., back side in the Y-direction) memory cell 210. As shown in FIG. 6A, each of conductive region 741F and 741B can be structured as strip of conductive material electrically separated from adjacent conductive regions of other access lines (e.g., access lines associated with signals WL and WLi).

In another example, as shown in FIG. 6A, the access line associated with signal WLi can include a conductive region (e.g., front conductive region) 749F and a conductive region (e.g., back conductive region) 749B. Conductive regions 749F and 749B can be part of an access line associated with memory cell 299. As shown in FIG. 6A, each of conductive region 749F and 749B can be structured as a strip of conductive material electrically separated from adjacent conductive regions of other access lines (e.g., access lines associated with signals WL and WL1). Conductive regions 749F and 749B are opposite from each other in the Y-direction. For example, conductive region 749F can be located on one side (e.g., front side in the Y-direction) of memory cell 299. Conductive region 749B can be located on another side (e.g., back side in the Y-direction) memory cell 299.

In alternative structure of memory device 200, instead of two conductive regions (e.g., conductive regions 741F and 741B), an access line of memory device 200 may include only one conductive region. For example, in alternative structure of memory device 200, one of conductive regions 741F and 741B and one of conductive regions 749F and 749B can be omitted from (not included in) memory device 200.

As shown in FIG. 6A, memory device 200 can include data lines associated with signals (e.g., bit line signals) BLR, BLW, BLR₁, BLW₁, BLRi, and BLWi. The data lines associated with signals BLR, BLW, BLR₁, BLW₁, BLRi, and BLWi are sometimes called data lines BLR, BLW, BLR₁, BLW₁, BLRi, and BLWi. For simplicity, some of the different data lines (e.g., read data lines) are associated with the same signal BLR, some of other different data lines (e.g., write data lines) are associated with the same signal BLW.

Each memory cell of memory device 200 can be associated with two data lines BLR and BLW (e.g., read and write data lines, respectively). Memory cells of the same tier (e.g., tier 602) in the X-direction can be associated with different data lines. For example, in tier 602, memory cell 210 is associated with data lines BLR₁ and BLW₁. Memory cell 299 (in tier 602) is associated with data lines BLRi and BLWi. Memory cell 299 is not schematically shown in FIG. 2. Memory cell 210 in FIG. 6A can correspond to memory cell 210 of FIG. 2. Data lines BLR₁ and BLW₁ in FIG. 6A can correspond to data lines 221R and 221W, respectively, of FIG. 2.

FIG. 6A shows an example of eight memory cells and 16 associated data lines of memory device 200. However, memory device 200 can include numerous memory cells and associated data lines.

Each of the data lines can include a conductive structure. For simplicity, only conductive structures 760R and 760W (associated with signals BLR and BLW, respectively), 761R and 761W (associated with signals BLR₁ and BLW₁, respectively), 762R and 762W (associated with signals BLRi and BLWi, respectively), 763R and 7623 (associated with signals BLR and BLW, respectively) are labeled in FIG. 6A.

As shown in FIG. 6A, each of the data lines can have a length in the Y-direction, which is a direction perpendicular to the direction from one tier (e.g., tier 601) to another tier (e.g., tier 601) of memory device 200. Thus, in memory device 200, the data lines can have lengths in a direction (e.g., in a horizontal direction) that is perpendicular to the length (e.g., in a vertical direction) of the access lines of memory device 200.

Memory device 200 can include a dielectric portion (which includes a dielectric material) 795 between conductive structures of adjacent data lines. For example, memory device 200 can include dielectric portion 795 between conductive structures 760W and 761W of data lines (e.g., write data lines) BLW and BLW₁, respectively. In another example, memory device 200 can include dielectric portion 795 between conductive structures 760R and 761R of data lines (e.g., read data lines) BLR and BLR₁, respectively.

As shown in FIG. 6A, memory device 200 can also include conductive lines (e.g., common conductive lines) associated with signals PLT and PLT1. Each of these conductive lines can include a respective conductive structure such as conductive structures 796 and 797. Each of conductive structures 796 and 797 can include a conductive material (e.g., conductively doped polysilicon, metal, or other conductive materials). Each of conductive structures 796 and 797 can have lengths in the Z-direction.

Each of conductive structures 796 and 797 can be a common conductive structure between adjacent memory cells in the Z-direction (FIG. 6A) of different tiers (e.g., tiers 601 and 602) and between adjacent memory cells in the X-direction of the same tier (e.g., tier 602). For example, FIG. 6A shows conductive structure 797 between memory cells 210 and 299 in the X-direction.

Each of conductive structures 796 and 797 of a respective conductive line (e.g., conductive line associated with signal PLT or PLT1) can be coupled to (or can be part of) a connection (e.g., connection 297) of memory device 200. In an operation of memory device, signals PLT and PLT1 can be provided with a voltage (e.g., voltage V3 or V6 in FIG. 3). Alternatively, signals PLT and PLT1 can be provided with a ground potential (e.g., coupled to a ground connection).

FIG. 6B shows a top view (e.g., a cross-section) of the structure of memory device 200 along line 6B-6B of FIG. 6A including data lines (e.g., write data lines) BLW, and BLW₁, and BLWi associated with the memory cells in tier 602 of FIG. 6A. As shown in FIG. 6B, data lines BLW, BLW₁, and BLWi can have lengths in the Y-direction. Memory cells of the same tier (e.g., tier 602) in the Y-direction can share data lines. For example, as shown in FIG. 6B, memory cells in the Y-direction (e.g., in the same column) can share data line BLW of conductive structure 763W, data line BLW of conductive structure 760W, data line BLW₁ of conductive structure 761W, or data line BLWi of conductive structure 762W.

As shown in FIG. 6B, from the top view with respect to the X-Y direction (e.g., X-Y plane), conductive region 741F and conductive region 741B can be located on opposite sides (e.g., front and back sides) of memory cell 210. Each of conductive regions 741F and 741B can be separated from memory cell 210 by a respective dielectric portion (e.g., a gate oxide) 717. Dielectric portion 717 can include a dielectric material. Example dielectric materials for dielectric portion 717 include silicon dioxide, silicon nitride, hafnium oxide (e.g., HfO₂), aluminum oxide (e.g., Al₂O₃), or other dielectric materials (e.g., other high-k dielectric materials). Conductive regions 741F and 741B can collectively be part of access line 241 (FIG. 2). Alternatively, conductive regions 741F and 741B can part of access lines 241 and 241′, respectively, of FIG. 5. Each of conductive regions 741F and 741B can include a conductive material (e.g., conductively doped polysilicon, metal, or other conductive materials).

As shown in FIG. 6B, memory cell 299 adjacent memory cell 210 in the X-direction also includes conductive portions (as part of the access line associated with signals WLi) 749F and 749B located on opposite sides (e.g., front and back sides) of memory cell 210. Each of conductive regions 749F and 749B can be separated from memory cell 210 by a respective dielectric portion (e.g., a gate oxide) 717. As shown in FIG. 6B, memory device 200 also includes other memory cells and other access lines (associated with signals WL). For simplicity, the structures of other memory cells and access lines are not described in detail.

In memory device 200, adjacent memory cells in the X-direction may not share an access line (e.g., a word line) or access lines. For example, in FIG. 6B, memory cells 210 and 299 may not share an access line or access lines. Thus, conductive regions 741F and 749F can be electrically separated from each other. For example, conductive regions 741F and 749F are not formed from (e.g., are included in) the same piece of conductive material. Similarly, conductive regions 741B and 749B can be electrically separated from each other. For example, conductive regions 741B and 749B are not formed from (e.g., are not included in) the same piece of conductive material.

FIG. 6C shows a top view (e.g., a cross-section) of the structure of memory device 200 along line 6C-6C of FIG. 6A including data lines (e.g., read data lines) BLR, BLR₁, and BLRi associated with the memory cells in tier 602 of FIG. 6A. FIG. 6C shows elements of memory device 200 that are similar to or the same as the elements of memory device 200 of FIG. 6B except for the read data lines (instead of the write data lines of FIG. 6B). As shown in FIG. 6C, data lines BLR, BLR₁, and BLRi can have lengths in the Y-direction. Memory cells in the Y-direction (e.g., in the same column) can share data line BLR of conductive structure 763R, data line BLR of conductive structure 760R, data line BLR₁ of conductive structure 761R, or data line BLRi of conductive structure 762R.

FIG. 6D shows an example of memory device 200 of FIG. 6A in which respective conductive regions (e.g., conductive regions 741F and 741B or conductive regions 749F and 749B) can be electrically coupled to each other by a connection 740. Connection 740 can include a conductive connection (which can include a conductive material (e.g., metal)).

FIG. 6E shows an example of memory device 200 of FIG. 6A in which respective conductive regions (e.g., conductive regions 741F and 741B or conductive regions 749F and 749B) are electrically separated from each other. For example, conductive regions 741F and 741B in FIG. 6E can be part of access lines 241 and 241′, respectively, in FIG. 5. As shown in FIG. 6E, conductive regions 741F and 741B of the access line associated with signals WL1 and WL1′ can be coupled to different drivers 231 and 231′, respectively. Drivers 231 and 231′ are the same as those shown in FIG. 2. As shown in FIG. 6E, conductive regions of other access lines (e.g., access lines associated with signals WL, WL′, WLi, and WLi′) can also be coupled different drivers.

FIG. 7 shows details of a side view (e.g., a cross-section) of the portion labeled “7” of memory device 200 in FIG. 6A including details of tiers 601 and 602. In FIG. 7, the same elements of memory cells 210 and 299 and other elements of memory device 200 are given the same labels.

As shown in FIG. 7, each of tiers 601 and 602 can have different levels (physical levels) located (stacked) one over another in the Z-direction over substrate 699. For example, tier 602 can include levels 771, 772, 773, 774, and 775. For simplicity, some of the other levels of memory device 200 including the levels within tier 601 are not labeled.

As shown in FIG. 7, conductive structures 761R and 761W of data lines BLR₁ and BLW₁, respectively, associated with memory cell 210 can be located on levels 772 and 774, respectively. Conductive structures 762R and 762W of data lines BLRi and BLWi, respectively, associated with memory cell 299 can be located on levels 772 and 774, respectively. For simplicity, similar conductive structures of the data lines associated with other memory cells of tier 601 are not described in detail.

Each of conductive structures 761R, 761W, 762R, and 762W can include a conductive material (e.g., conductively doped polysilicon, metal, or other conductive materials) having a length in the Y-direction.

Conductive structures 761R, 761W, 762R, and 762W can be electrically coupled to some of the elements (e.g., read and write channel regions of respective transistors T1 and T2, described below) of respective memory cells (e.g., memory cell 210 and 299) among the memory cells of tier 602. Each of conductive structures 761R, 761W, 762R, and 762W are electrically separated from the access lines (e.g., access lines associated with signals WL1 and WLi) of memory device 200 by respective dielectric portions (e.g., dielectric portions 717 shown in FIG. 6B).

A shown in FIG. 7, memory device 200 can include different dielectric portions located on different levels in the Z-direction to electrically separate the elements (in the Z-direction) within the same tier and to electrically separate one tier from another tier. For example, memory device 200 can include dielectric portions (e.g., tier isolation structures) 765 to separate the memory cells of adjacent tiers (e.g., tiers 601 and 602) from each other. Memory device 200 can also include dielectric portions 715, 718, and 719 located on levels 774, 773, and 775, respectively, to separate (e.g., electrically separate) elements of the same memory cell (e.g., memory cell 210) from each other or to separate (e.g., electrically separate) elements of a memory cell (e.g., memory cell 210) from other elements (e.g., data lines and access lines) of memory device 200.

For simplicity, the description of FIG. 7 describes the elements of tier 602. Tier 601 can have similar elements (which have similar or the same labels) as the elements of the elements (e.g., memory cell 210) of tier 602.

Dielectric portions 715, 718, and 719 can have the same dielectric material or different dielectric materials. Example materials for dielectric portions 715, 718, 719, and 765 include silicon oxide, silicon nitride, hafnium oxide (e.g., HfO₂), aluminum oxide (e.g., Al₂O₃), or other dielectric materials (e.g., other high-k dielectric materials). In an example, dielectric portion 719 can have a dielectric material that is different from the dielectric material of dielectric portion 718. For example, dielectric portion 719 can include silicon oxide, and dielectric portion 718 can include a high-k dielectric material (e.g., HfO₂, Al₂O₃, or other high-k dielectric materials). Dielectric portion 717 (FIG. 6B and FIG. 6C) and one or more of dielectric portions 715, 718, and 719 can have the same dielectric material or different dielectric materials. For example, dielectric portions 717 and 718 can have the same dielectric material or different dielectric materials. In an example, dielectric portion 717 can include silicon oxide, and dielectric portion 718 can include a high-k dielectric material (e.g., HfO₂, Al₂O₃, or other high-k dielectric materials). A high-k dielectric material is a dielectric material having a dielectric constant greater than the dielectric constant of silicon dioxide. Using a high-k dielectric material (e.g., instead of silicon dioxide) for dielectric portion 718 can improve operation of the memory cells (e.g., memory cells 210 and 299) of memory device 200.

FIG. 7 shows dielectric portion 719 as a single structure (e.g., a single layer of dielectric material in the Z-direction) as an example. However, dielectric portion 719 can include multiple structures (e.g., multiple layers of different dielectric materials stacked one over another in the Z-direction).

As shown in FIG. 7, memory device 200 can include a charge storage structure 702 and a material 720 located on level 774. Material 720 can also be called portion 720. Material 720 is adjacent (e.g., contacts) charge storage structure 702 and is electrically coupled to charge storage structure 702. Material 720 can also be electrically coupled to (can contact) a respective conductive structure (e.g., conductive structure 761W or 762W) of a respective data line (e.g., data line BLW₁ or BLWi).

As shown in FIG. 7, each of memory cells 210 and 299 of memory device 200 can include transistor T2. Material 720 can form part of a channel region (e.g., write channel region) of transistor T2 of a respective memory cell (e.g., memory cell 210 or 299).

Material 720 (also called portion 720) of a particular memory cell (e.g., memory cell 210) can form a source (e.g., source terminal), a drain (e.g., drain terminal), or a channel region (e.g., write channel region) between the source and the drain of transistor T2 of that particular memory cell (e.g., memory cell 210). For example, as shown in FIG. 7, the source, channel region, and the drain of transistor T2 of memory cell 210 can be formed from a single piece of the same material (or alternatively, a single piece of the same combination of materials) such as material 720. Therefore, the source, the drain, and the channel region of transistor T2 of memory cell 210 can be formed from the same material (e.g., material 720) of the same conductivity type (e.g., either n-type or p-type).

Material 720 (e.g., the write channel region of transistor T2) of a particular memory cell (e.g., memory cell 210) of memory device 200 can be part of a write path of that particular memory cell. For example, material 720 of memory cell 210 can be part of a write path of memory cell 210 that can carry a current (e.g., write current) during a write operation of storing information in memory cell 210. For example, during a write operation, to store information in memory cell 210 in FIG. 7, material 720 of memory cell 210 can conduct a current (e.g., write current) between conductive structure 761W and charge storage structure 702 of memory cell 210. The direction of the write current can be from conductive structure 761W to charge storage structure 702 of memory device 200. In the example where transistor T2 is an NFET (e.g., a NMOS), the current (e.g., write current) can include an electron conduction (e.g., electron conduction in the direction from conductive structure 761W to charge storage structure 702 through material 720 (the channel region of transistor T2) of memory cell 210.

Material 720 can include a structure (e.g., a piece (e.g., a layer)) of semiconductor material. In the example where transistor T2 is an NFET (as described above), material 720 can include n-type semiconductor material (e.g., n-type silicon).

In another example, the semiconductor material that forms material 720 can include a piece of oxide material. Examples of the oxide material used for material 720 include semiconducting oxide materials, transparent conductive oxide materials, and other oxide materials.

As an example, material 720 can include at least one of zinc tin oxide (ZTO), indium zinc oxide (IZO), zinc oxide (ZnOₓ), indium gallium zinc oxide (IGZO), indium gallium silicon oxide (IGSO), indium oxide (InOₓ, In₂O₃), tin oxide (SnO₂), titanium oxide (TiOx), zinc oxide nitride (ZnₓO_{y}N_{z}), magnesium zinc oxide (MgₓZn_{y}O_{z}), indium zinc oxide (InₓZn_{y}O_{z}), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), indium gallium silicon oxide (InGaSiO), and gallium phosphide (GaP).

Using the material listed above in memory device 200 provides improvement and benefits for memory device 200. For example, during a read operation, to read information from a selected memory cell (e.g., memory cell 210), charge from charge storage structure 702 of the selected memory cell may leak to transistor T2 of the selected memory cell. Using the material listed above for the channel region (e.g., material 720) of transistor T2 can reduce or prevent such a leakage. This improves the accuracy of information read from the selected memory cell and improves the retention of information stored in the memory cells of the memory device (e.g., memory device 200) described herein.

The materials listed above are examples of material 720. However, other materials (e.g., a relatively high band-gap material) different from the above-listed materials can be used.

As shown in FIG. 7, charge storage structure 702 is adjacent (e.g., contacts) material 720 and electrically coupled to material 720. Charge storage structure 702 can correspond to charge storage structure 202 of memory device 200 that is schematically shown in FIG. 2. As shown in FIG. 7, charge storage structure 702 is electrically separated from conductive structure 797 of a respective conductive line (e.g., the conductive line associated with signal PLT1) by dielectric portion 715. Charge storage structure 702 can include a charge storage material (or a combination of materials), which can include a piece (e.g., a layer) of semiconductor material (e.g., polysilicon), a piece of conductive semiconductor material, a piece (e.g., a layer) of metal, or a combination of these materials (e.g., metal and conductive semiconductor material) or a piece of material (or materials) that can trap charge. The materials for charge storage structure 702 and conductive regions 741F, 741B, 749F, and 749B can be the same or can be different.

Memory device 200 can include a portion 710 on level 772. Portion 710 is adjacent one side (e.g., bottom side) of dielectric portion 718 and separated from portion 720 and charge storage structure 702 by dielectric portion 718. Portion 720 and charge storage structure 702 are adjacent another side (e.g., top side) of dielectric portion 718 and separated from portion 710 by dielectric portion 718. Portion 710 can be electrically coupled to (can contact) conductive structure 797. Portion 710 can also be electrically coupled to (can contact) one of conductive structures 761R and 762R of a respective data line (the data line BLR₁ or BLRi).

As shown in FIG. 7, each of memory cells 210 and 299 can include transistor T1. Portion 710 can form part of a channel region (e.g., read channel region) of transistor T1 of a respective memory cell (e.g., memory cell 210 or 299).

Portion 710 of a particular memory cell (e.g., memory cell 210) can form a source (e.g., source terminal), a drain (e.g., drain terminal), or a channel region (e.g., write channel region) between the source and the drain of transistor T1 of that particular memory cell (e.g., memory cell 210). For example, as shown in FIG. 7, the source, channel region, and the drain of transistor T1 of memory cell 210 can be formed from a single piece of the same material (or alternatively, a single piece of the same combination of materials) such as portion 710. Therefore, the source, the drain, and the channel region of transistor T1 of memory cell 210 can be formed from the same material (e.g., the material of portion 710) of the same conductivity type (e.g., either n-type or p-type).

Portion 710 can include a semiconductor material. Example materials for portion 710 include silicon, polysilicon (e.g., undoped or doped polysilicon), germanium, silicon-germanium, or other semiconductor materials, and semiconducting oxide materials (oxide semiconductors, e.g., SnO or other oxide semiconductors). The semiconductor material of portion 710 and the semiconductor material of portion 720 can have different conductivity types (e.g., n-type conductivity and p-type conductivity). Alternatively, the semiconductor material of portion 710 and the semiconductor material of portion 720 (material 720) can have the same conductivity type (e.g., n-type conductivity or p-type conductivity).

Portion 710 (e.g., the read channel region of transistor T1) of a particular memory cell (e.g., memory cell 210) of memory device 200 can be part of a read path of that particular memory cell. For example, portion 710 of memory cell 210 can be part of a read path of memory cell 210 that can carry a current (e.g., read current) during a read operation of reading information from memory cell 210. For example, during a read operation, to read information from memory cell 210 in FIG. 7, portion 710 of memory cell 210 can conduct a current (e.g., read current) between conductive structure 761R and conductive structure 797. The direction of the read current can be from conductive structure 761R to conductive structure 797 through portion 710. In the example where transistor T1 is a PFET (e.g., a PMOS), the current (e.g., read current) can include a hole conduction (e.g., hole conduction in the direction from conductive structure 761R to conductive structure 797 through portion 710 (the channel region of transistor T1)) of memory cell 210.

In the example where transistor T1 is a PFET and transistor T2 is an NFET, the material that forms portion 710 can have a different conductivity type from the material of portion 720. For example, portion 710 can include p-type semiconductor material (e.g., p-type silicon) regions, and the material of portion 720 can include n-type semiconductor material (e.g., n-type gallium phosphide (GaP)) regions.

As shown in FIG. 7, conductive region 741F can be opposite (in the Y-direction) portion 720 and charge storage structure 702 of memory cell 210 and can form a gate of transistor T2 of memory cell 210. Conductive region 741F can also be opposite (in the y-direction) portion 710 of memory cell 210 and can form a gate of transistor T1 of memory cell 210. Similarly, conductive region 741B can be opposite (in the y-direction) portion 720 and charge storage structure 702 of memory cell 210 and can form a gate of transistor T2 of memory cell 210. Conductive region 741B can also be opposite (in the y-direction) portion 710 of memory cell 210 and can form a gate of transistor T1 of memory cell 210. Thus, the same signal (e.g., WL1) can be used to control (e.g., turn on or turn off) transistors T1 and T2 of memory cell 210 in a structure (e.g., FIG. 6D) where conductive regions 741F and 741B are electrically coupled (e.g., short) to each other (e.g., coupled to each other by a respective connection 740 in FIG. 6D). Alternatively, different signals (e.g., signals WL1 and WL1′ in FIG. 6E) can be used and separately provided to conductive regions 741F and 741B.

Conductive regions 749F and 749B can be associated with memory cell 299 in similar ways as conductive regions 741F and 741B associated with memory cell 210. As shown in FIG. 7, conductive region 749F can be opposite (in the y-direction) portion 720 and charge storage structure 702 of memory cell 299 and can form a gate of transistor T2 of memory cell 299. Conductive region 749F can also be opposite (in the y-direction) portion 710 of memory cell 299 and can form a gate of transistor T1 of memory cell 299. Similarly, conductive region 749B can be opposite (in the y-direction) portion 720 and charge storage structure 702 of memory cell 299 and can form a gate of transistor T2 of memory cell 299. Conductive region 749B can also be opposite (in the y-direction) portion 710 of memory cell 299 and can form a gate of transistor T1 of memory cell 299. Thus, the same signal (e.g., WL1) can be used to control (e.g., turn on or turn off) transistors T1 and T2 of memory cell 299 in a structure (e.g., FIG. 6D) where conductive regions 749F and 749B are electrically coupled (e.g., short) to each other (e.g., coupled to each other by a respective connection 740 in FIG. 6D). Alternatively, different signals (e.g., signals WLi and WLi′ in FIG. 6E) can be used and separately provided to conductive regions 749F and 749B.

The descriptions above with reference to FIG. 6A through FIG. 7 show that the elements (e.g., the memory cells and the access lines) can be arranged (e.g., formed) in different tiers in memory device 200. This can allow multiple tiers (e.g., tiers 601 and 602 and similar tiers) of memory device 200 to be formed together. Thus, the cost (e.g., cost per bit) of forming memory device 200 can be reduced.

Each memory cell (e.g., memory cell 210) of memory device 200 can be associated with a single data line (instead of two data lines described above) for both read and write operation of a selected memory cell. However, associating two data lines (e.g., read and write data lines as described above) with a memory cell as described herein can improve operation of memory device 200. For example, in a single data line structure (e.g., data lines 221R and 221W in FIG. 4 are the same data line or shorted to each other), the selected data line (e.g., data line 221W) associated with a selected memory cell (e.g., memory cell 210 in FIG. 4) in a write operation may be provided with a relatively high voltage (e.g., 1V). In this example, transistor T1 of an unselected memory cell (e.g., memory cell 212 in FIG. 4) that shares the single data line with the selected memory cell may be configured with a relatively high threshold voltage (e.g., higher gate-to-source voltage Vgs). The relatively high threshold voltage is configured to properly turn off transistor T1 (e.g., to properly maintain off-state current (Ioff) of transistor T1) of the unselected memory cell that shares the single data line with the selected memory cell. Such a high threshold voltage may degrade on-state current (Ion) of transistor T1 during a read operation of a selected memory cell of memory device 200. However, in memory device 200 of FIG. 6A and FIG. 7, associating two data lines (e.g., read and write data lines) with a memory cell (e.g., data lines BLR₁ and BLW₁ in memory cell 210 of FIG. 6A and FIG. 7) can relax the (e.g., reduce) the threshold voltage for transistor T1. This can improve operations (e.g., read operations) of memory device 200.

The illustrations of apparatuses (e.g., memory devices 100 and 200) and methods (e.g., operations of memory devices 100 and 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., an electronic item that can include any of memory devices 100 and 200).

Any of the components described above with reference to FIG. 1 through FIG. 7 can be implemented in a number of ways, including simulation via software. Thus, apparatuses (e.g., memory devices 100 and 200) or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100 and 200) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 7 include apparatuses and methods of using the apparatuses. One of the apparatuses includes: a first conductive structure located on a first level of the apparatus; a second conductive structure located on a second level of the apparatus, each of the first and second conductive structures including a length in a first direction; a memory cell including a first semiconductor portion located on the first level and coupled to the first conductive structure, a charge storage structure located on the first level and coupled to the first semiconductor portion, and a second semiconductor portion located on the second level and coupled to the second conductive structure; and a conductive region adjacent the first and second semiconductor portions, the conductive region including a length in a second direction and separated from the first and second semiconductor portions by a dielectric material. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first conductive structure located on a first level of the apparatus;
a second conductive structure located on a second level of the apparatus, each of the first conductive structure and the second conductive structure including a length in a first direction;
a memory cell including:
a first semiconductor portion located on the first level and coupled to the first conductive structure;
a charge storage structure located on the first level and coupled to the first semiconductor portion; and
a second semiconductor portion located on the second level and coupled to the second conductive structure; and
a conductive region adjacent the first semiconductor portion and the second semiconductor portion, the conductive region including a length in a second direction and separated from the first semiconductor portion and the second semiconductor portion by a dielectric material.

2. The apparatus of claim 1, further comprising an additional conductive region, wherein the conductive region is adjacent a first side of the first semiconductor portion and a first side of the second semiconductor portion, and wherein:
the additional conductive region is adjacent a second side of the first semiconductor portion and a second side of the second semiconductor portion, the additional conductive region including a length in the second direction and separated from the second side of the first semiconductor portion and the second side of the second semiconductor portion by an additional dielectric material.

3. The apparatus of claim 2, wherein the conductive region and the additional conductive region are coupled to each other.

4. The apparatus of claim 1, wherein:
the first conductive structure is part of a first data line of the apparatus; and
the second conductive structure is part of a second data line of the apparatus.

5. The apparatus of claim 1, wherein the conductive region is part of a word line of the apparatus.

6. The apparatus of claim 1, wherein the first semiconductor portion and second semiconductor portion have different conductivity types.

7. The apparatus of claim 1, wherein the first semiconductor portion and second semiconductor portion have a same conductivity type.

8. The apparatus of claim 1, wherein the first semiconductor portion includes a semiconducting oxide material.

9. The apparatus of claim 9, further comprising an additional dielectric material between the first semiconductor portion and the second semiconductor portion, wherein the dielectric material and the additional dielectric material have different materials.

10. The apparatus of claim 1, further comprising:
a first additional conductive structure located on the first level;
a second additional conductive structure located on the second level, each of the first additional conductive structure and the second additional conductive structure including a length in the first direction;
an additional memory cell including:
a first additional semiconductor portion located on the first level and coupled to the first additional conductive structure;
an additional charge storage structure located on the first level and coupled to the first additional semiconductor portion;
a second additional semiconductor portion located on the second level and coupled to the second additional conductive structure; and
an additional conductive region adjacent the first additional semiconductor portion and the second additional semiconductor portion, the additional conductive region including a length in the second direction and separated from the first additional semiconductor portion and the second additional semiconductor portion by an additional dielectric material; and
a third conductive structure coupled to the second semiconductor portion and the second additional semiconductor portion.

11. An apparatus comprising:
a first data line located on a first level of the apparatus;
a second data line located on a second level of the apparatus;
a third data line located on the first level;
a fourth data line located on the second level;
a first memory cell including:
a first channel region located on the first level and coupled to the first data line; and
a second channel region located on the second level and coupled to the second data line; and
a second memory cell including:
a third channel region located on the first level and coupled to the third data line; and
a fourth channel region located on the second level and coupled to the fourth data line.

12. The apparatus of claim 11, further comprising a conductive structure coupled to the second channel region and the fourth channel region.

13. The apparatus of claim 11, further comprising:
a first conductive region adjacent a side of the first channel region and a side of the second channel region; and
a second conductive region adjacent a side of the third channel region and a side of the fourth channel region.

14. The apparatus of claim 13, wherein each of the first conductive region and the second conductive region includes a length in a direction from the first level to the second level.

15. The apparatus of claim 11, wherein each of the first data line and the third data line includes a length in a direction perpendicular to a direction from the first level to the second level.

16. The apparatus of claim 11, wherein:
each of the first channel region and the third channel region includes a first semiconductor material having n-type conductivity; and
each of the second channel region and the fourth channel region includes a second semiconductor material having p-type conductivity.

17. The apparatus of claim 11, wherein the second channel region includes at least one of zinc tin oxide (ZTO), indium zinc oxide (IZO), zinc oxide (ZnOₓ), indium gallium zinc oxide (IGZO), indium gallium silicon oxide (IGSO), indium oxide (InOₓ, In₂O₃), tin oxide (SnO₂), titanium oxide (TiOx), zinc oxide nitride (ZnₓO_{y}N_{z}), magnesium zinc oxide (MgₓZn_{y}O_{z}), indium zinc oxide (InₓZn_{y}O_{z}), indium gallium zinc oxide (InₓGa_{y}Zn₂Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), indium gallium silicon oxide (InGaSiO), and gallium phosphide (GaP).

18. An apparatus comprising:
tiers located one over another, each of the tiers including memory cells;
a first data line associated with a memory cell of the memory cells;
a second data line associated with the memory cell, the memory cell including:
a first transistor coupled to the first data line; and
a second transistor coupled to the second data line;
a first conductive region adjacent a first side of the first transistor and a first side of the second transistor; and
a second conductive region adjacent a second side of the first transistor and a second side of the second transistor, each of the first conductive region and the second conductive region including a length in a direction from a first tier of the tiers to a second tier of the tiers.

19. The apparatus of claim 18, further comprising a conductive structure coupled to the second transistor and including a length in a direction from a first tier of the tiers to a second tier of the tiers.

20. The apparatus of claim 18, wherein:
the first transistor includes a first channel region and a charge storage structure separate from the first channel region, the first channel region including a semiconductor material having a first conductivity type; and
the second transistor includes a second channel region coupled to the charge storage structure, the second channel region including a second semiconductor material having a second conductivity type.
